(19) United States
(12) Patent Application Publication
(10) Pub. No.: US 2006/0145220 A1
(43) Pub. Date: Jul. 6, 2006

(54) CMOS image sensor and method for fabricating the same

(76) Inventor: Joon Hwang, Cheongju-city (KR)

Correspondence Address: MCKENNA LONG & ALDRIDGE LLP, 1900 K STREET, NW, WASHINGTON, DC, 20006, US

(21) Appl. No.: 11/320,343

(22) Filed: Dec. 29, 2005

(30) Foreign Application Priority Data
Dec. 30, 2004 (KR) 10-2004-0117223

(51) Int. Cl. H01L 31/062; H01L 21/00

(52) U.S. Cl. 257/294; 438/70; 359/619; 257/432

(57) ABSTRACT

Provided are a CMOS image sensor which has an infrared ray cut-off filter formed therein such that the size of a camera module of a portable telephone can be reduced and manufacturing yield can be improved and a method of manufacturing the same. The CMOS image sensor includes a color filter layer formed on a semiconductor substrate in which a photodiode region, a gate electrode, an interlayer insulating layer, and a metal line are formed, an infrared ray cut-off filter formed on the color filter layer, and a micro lens formed on the infrared ray cut-off filter.

### CROSS REFERENCE TO RELATED APPLICATION

This application claims the benefit of the Korean Patent Application No. P2004-117223, filed on Dec. 30, 2004, which is hereby incorporated by reference for all purposes as if fully set forth herein.

### BACKGROUND OF THE INVENTION

1. Field of the Invention

The present invention relates to a semiconductor device, and more particularly, to a CMOS image sensor having an infrared ray cut-off filter and a method of manufacturing the same.

2. Discussion of the Related Art

Generally, an image sensor is a semiconductor device that converts an optical image to an electric signal. In a CCD (charge coupled device) image sensor, a plurality of MOS (metal-oxide-metal) capacitors are arranged close to one another to transfer and store electric charge carriers. In a CMOS (complementary MOS) image sensor, a plurality of MOS transistors amounting to the number of pixels are fabricated by the CMOS technology using a control circuit and a signal processing circuit as peripheral circuits and a switching system of detecting outputs step by step using the MOS transistors is adopted.

The CMOS image sensor includes signal processing chips having a photodiode. An amplifier, an analog/digital converter, an internal voltage generator, a timing generator, and a digital logic may be incorporated in one chip, thereby reducing space, power, and cost. The CMOS image sensor is manufactured using a method of etching a silicon wafer, which is cheaper than the method of manufacturing the CCD. Thus, the CMOS image sensor is advantageous for mass production and the degree of integration.

Hereinafter, a CMOS image sensor according to the related art will be described in detail with reference to the attached drawings.

FIG. 1 is a cross-sectional view of the CMOS image sensor according to the related art.

Necessary components 16 such as a photodiode region, a gate electrode, an interlayer insulating layer, and a metal line are formed on a semiconductor substrate 15, a color filter layer 17 is formed on the necessary components 16, a passivation layer 18 composed of a photoresist is formed on the color filter layer 17, and a micro lens 19 is formed on the planarization layer 18.

FIG. 2 illustrates a construction of a camera using a CMOS image sensor shown in FIG. 1.

A CMOS image sensor 11 is positioned on a PCB substrate 10, an infrared ray cut-off filter 12 for preventing the photoelectric effect due to infrared rays is provided above the CMOS image sensor 11, a lens 13 for transmitting light is positioned above the infrared ray cut-off filter 12, and a housing in which the PCB substrate 10, the infrared ray cut-off filter 12, and the lens 13 are mounted is provided. The light passing through the lens 13 passes through the infrared ray cut-off filter 12 and is irradiated onto the image sensor 11 in an inverted image.

However, when a camera module of a portable telephone is manufactured using the CMOS image sensor according to the prior art, the infrared ray cut-off filter coated on quartz must be separately provided. Thus, there is a minimum size the camera module can be and thus the manufacturing yield is reduced.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is that it provides a CMOS image sensor which has an infrared ray cut-off filter formed therein such that the size of a camera module of a portable telephone can be reduced and manufacturing yield can be improved, and a method of manufacturing the same.

Additional advantages, and features of the invention will be set forth in part in the description which follows, and will become apparent from the description, or may be learned by practice of the invention. These and other advantages of the invention may be realized and attained by the structure particularly pointed out in the written description and claims hereof as well as the appended drawings.

To achieve these and other advantages and in accordance with the purpose of the invention, as embodied and broadly described herein, a CMOS image sensor according to the present invention includes a color filter layer formed on a semiconductor substrate in which a photodiode region, a gate electrode, an interlayer insulating layer, and a metal line are formed, an infrared ray cut-off filter formed on the color filter layer, and a micro lens formed on the infrared ray cut-ff filter.

According to another aspect of the present invention, there is provided a method of manufacturing a CMOS image sensor including forming a color filter layer on a semiconductor substrate in which a photodiode region, a gate electrode, an interlayer insulating layer, and a metal line are formed, forming an infrared ray cut-off filter on the color filter layer, and forming a micro lens on the infrared ray cut-off filter.

It is to be understood that both the forgoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIG. 1 is a cross-sectional view of the CMOS image sensor according to the related art;

FIG. 2 illustrates a construction of a camera using a CMOS image sensor shown in FIG. 1

FIG. 3 is a cross-sectional view of a CMOS image sensor having an infrared ray cut-off filter according to an exemplary embodiment of the present invention;

FIG. 4 illustrates a cut-off function of the infrared ray cut-off filter; and

FIG. 5 is a cross-sectional view of a CMOS image sensor in accordance with an exemplary embodiment of the present invention.

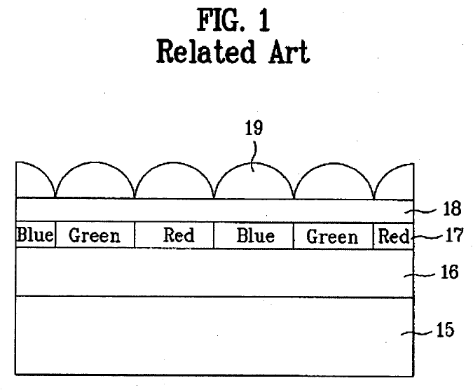

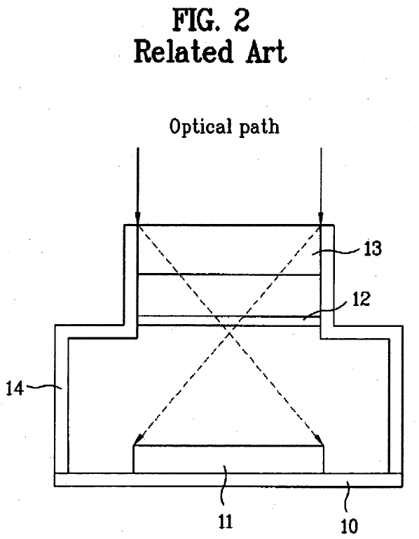

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or like parts.

Hereinafter, a CMOS image sensor having an infrared ray cut-off filter according to an exemplary embodiment of the present invention will be described in detail with reference to the attached drawings.

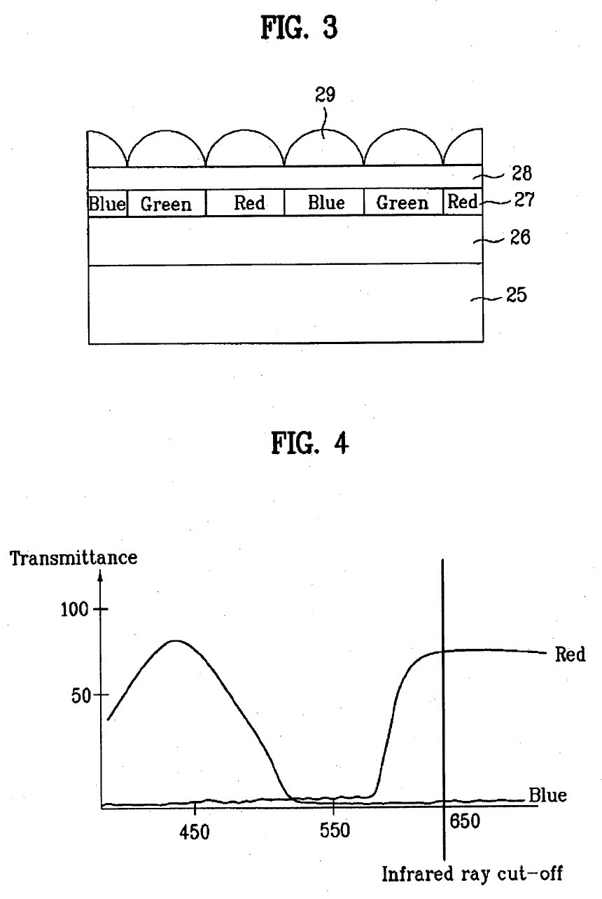

FIG. 3 is a cross-sectional view of a CMOS image sensor having an infrared ray cut-off filter according to an exemplary embodiment of the present invention.

Components 26 such as a photodiode region(not shown), a gate electrode(not shown), an interlayer insulating layer(not shown), and a metal line(not shown) are formed on a semiconductor substrate 25, a color filter layer 27 is formed on the components 26, and an infrared ray cut-off layer 28 is formed on the color filter layer 27. The infrared ray cut-ff layer 28 may have a thickness of approximately 1.0-3.0 μm.

The infrared ray cut-off filter 28 uses a photoresist having a filter pigment mixed therein. A micro lens 29 is formed on the infrared ray cut-off filter 28. The filter pigment may include at least two compounds selected from the group consisting of diammonium based compound, phthalocyanine based compound, and nickel complex based compound.

A micro lens 29 is formed on the infrared ray cut-off filter 28.

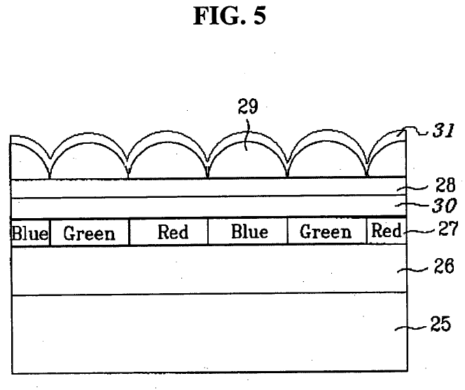

In the above embodiment of the present invention, infrared ray cut-off filter 28 is formed directly on the color filter layer 27. As shown in FIG. 5, in another embodiment of the present invention, a planarization layer 30 may be formed on the color filter layer 27, and infrared ray cut-off filter 28 is formed on the planarization layer. Also, an oxide layer 31 for protecting the micro lens 29 may be formed on the micro lens 29.

FIG. 4 illustrates a cut-off function of the infrared ray cut-off filter.

An X axis represents a wavelength and a Y axis represents transmittance. As shown in FIG. 4, in the CMOS image sensor having the infrared ray cut-off filter, the wavelength of at least 650 nm is cut off by the infrared ray cut-off filter.

According to the present invention, since a CMOS image sensor has an infrared ray cut-off filter formed therein, it is possible to reduce the size of a camera module of a portable telephone and improve manufacturing yield.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a semiconductor substrate in which a photodiode region, a gate electrode, an interlayer insulating layer, and a metal line are formed;
a color filter layer on the semiconductor substrate;
an infrared ray cut-off filter formed on the color filter layer; and
a micro lens formed on the infrared ray cut-off filter.

2. The CMOS image sensor according to claim 1, further comprising a planarization layer formed between the color filter layer and the infrared ray cut-off filter.

3. The CMOS image sensor according to claim 1, wherein the infrared ray cut-off filter is formed of a photoresist having a filter pigment mixed therein.

4. The CMOS image sensor according to claim 3, wherein the filter pigment includes at least two compounds selected from the group consisting of diammonium based compound, phthalocyanine based compound, and nickel complex based compound.

5. The CMOS image sensor according to claim 1, wherein the infrared ray cut-off filter has a thickness of about 1.0-3.0 μm.

6. The CMOS image sensor according to claim 1, further comprising an oxide layer formed on the micro lens for protecting the micro lens.

7. A method of manufacturing a CMOS image sensor comprising:
forming a color filter layer on a semiconductor substrate in which a photodiode region, a gate electrode, an interlayer insulating layer, and a metal line are formed;
forming an infrared ray cut-off filter on the color filter layer; and
forming a micro lens on the infrared ray cut-off filter.

8. The method according to claim 7, further comprising forming a planarization layer on the color layer before forming the infrared ray cut-off filter.

9. The method according to claim 7, wherein the infrared ray cut-off filter is formed of a photoresist having a filter pigment mixed therein.

10. The method according to claim 9, wherein the filter pigment includes at least two compounds selected from the group consisting of diammonium based compound, phthalocyanine based compound, and nickel complex based compound.

11. The method according to claim 7, wherein the infrared ray cut-off filter has a thickness of about 1.0-3.0 μm.

12. The method according to claim 7, further comprising forming an oxide layer on the micro lens for protecting the micro lens.
